(19) United States
(12) Patent Application Publication
(10) Pub. No.: US 2021/0018571 A1
(43) Pub. Date: Jan. 21, 2021

(54) METHOD FOR CONTROLLING POWER SUPPLIES

(71) Applicants: Te-Lung CHEN, Taoyuan City (TW); Chih-Cherng LU, Taoyuan City (TW); Shu-Che CHANG, Taoyuan City (TW); Shih-Hsun HSU, Taoyuan City (TW); Chia-Ching TING, Taoyuan City (TW)

(72) Inventors: Te-Lung CHEN, Taoyuan City (TW); Chih-Cherng LU, Taoyuan City (TW); Shu-Che CHANG, Taoyuan City (TW); Shih-Hsun HSU, Taoyuan City (TW); Chia-Ching TING, Taoyuan City (TW)

(21) Appl. No.: 16/926,800

(22) Filed: Jul. 13, 2020

(30) Foreign Application Priority Data
Jul. 16, 2019 (TW) 108124980

(51) Int. Cl. G01R 31/40; G06F 1/3206

(52) U.S. Cl. CPC G01R 31/40; G06F 1/3206

(57) ABSTRACT

The present invention discloses a method for controlling power supplies, each of M power supply has a first end and a second end, the first end of the i^{th} power supply is connected to the second end of the (i−1)^{th} power supply. The method comprises the following steps. A testing procedure is performed by each of the M power supplies for determining whether the first end and the second end are connected or not. A first connection status code is set when the testing procedure determines that the first end is connected, and the second end is not connected. A second connection status code is set when the testing procedure determines that the first end and the second end are both connected. A third connection status code is set when the testing procedure determines that the second end is connected, and the first end is not connected.

### BACKGROUND OF THE INVENTION

### Cross Reference to Related Application

The present application claims priority to Taiwan patent application Serial No. 108124980 filed on Jul. 16, 2019, the entire content of which is incorporated by reference to this application.

### 1. Field of the Invention

The present invention pertains to a method for controlling power supplies, in particular to a control method that can be set according to a physical position of the power supplies.

### 2. Description of the Prior Art

In electronic products testing procedure, a power supply is used to inspect electronic characteristics, such as voltage and current, of electronic products. Generally speaking, one power supply might be enough to provide testing current to small electronic products. However, the testing current that needs to be provided may be larger for some large electronic products or battery equipment, so that it is necessary to use multiple power supplies at the same time. In other words, a very large number of power supplies might be required if we want to conduct batch electrical testing of large electronic products or battery equipment. In practice, these power supplies will be divided into several groups, and each group of power supplies will be stacked or disposed in a cabinet.

The problem is that the power supply does not necessarily have a control panel. When one of the power supplies fails, engineers cannot visually determine which power supply is malfunctioned, and engineers need to manually check the power supplies one by one. On the other hand, the power supplies are often stacked in large numbers. The uppermost power supply may be positioned at a very high place, which may cause trouble or danger when inspected or tested by engineers.

### SUMMARY OF THE INVENTION

The present invention provides a method for controlling power supplies, which can know the number of power supplies in the same group, and can make various settings according to the physical position of each power supply. Therefore, when one of the of power supply groups is failed, the engineer can quickly know which power supply in that group is malfunctioned.

The present invention discloses a method for controlling power supplies that applies to M power supplies, each power supply has a first end and a second end, the first end of the i^{th} power supply is connected to the second end of the (i−1)^{th} power supply. The method for controlling power supplies comprises the following steps. A testing procedure is performed by each of the M power supplies for determining whether the first end and the second end are connected or not. A first connection status code is set when the testing procedure determines that the first end is connected, and the second end is not connected. A second connection status code is set when the testing procedure determines that the first end and the second end are both connected. A third connection status code is set when the testing procedure determines that the second end is connected, and the first end is not connected. Wherein M is a natural number greater than 2, and i is a natural number not less than 2 and not greater than M.

In some embodiments, the method for controlling power supplies further comprises the following steps. One of the M power supplies is set as a master power supply. And, the master power supply is determined whether it has the first connection status code, the second connection status code, or the third connection status code. A first addressing command and a first accumulated value are transmitted by the first end of the master power supply when the master power supply has the first connection status code. In addition, the first addressing command and the first accumulated value are transmitted by the first end of the master power supply, and a second addressing command and a second accumulated value are transmitted by the second end of the master power supply when the master power supply has the second connection status code. Besides, the second addressing command and the second accumulated value are transmitted by the second end of the master power supply when the master power supply has the third connection status code. Moreover, the j^{th} power supply is determined whether it has the second connection status code or the third connection status code when the second end of the j^{th} power supply receives the first addressing command and the first accumulated value. Further, the first accumulated value is updated, and a first completion command and the updated first accumulated value are transmitted by the second end of the j^{th} power supply when the j^{th} power supply has the third connection status code. Wherein j is a natural number not greater than M.

In some embodiments, the k^{th} power supply is determined whether it has the first connection status code or the second connection status code when the first end of the k^{th} power supply receives the second addressing command and the second accumulated value. In addition, the second accumulated value is updated, and the second addressing command and the updated second accumulated value are transmitted by the second end of the k^{th} power supply when the k^{th} power supply has the second connection status code. Besides, the second accumulated value is updated, and a second completion command and the updated second accumulated value are transmitted by the first end of the k^{th} power supply when the k^{th} power supply has the first connection status code. Wherein k is a natural number not greater than M.

In some embodiments, the number of the M power supplies is calculated at least according to the first accumulated value received by the first end of the master power supply or the second accumulated value received by the second end of the master power supply. A master position code of the master power supply is set at least according to the first accumulated value or the second accumulated value. A first setting command and a first position code are transmitted by the first end of the master power supply when the master power supply has the first connection status code. In addition, the first setting command and the first position code are transmitted by the first end of the master power supply, and a second setting command and a second position code are transmitted by the second end of the master power supply when the master power supply has the second connection status code. Besides, the second setting command and the second position code are transmitted by the second end of the master power supply when the master power supply has the third connection status code. Wherein the first position code and the second position code are related to the master position code.

In some embodiments, the j^{th} power supply is determined whether it has the second connection status code or the third connection status code when the second end of the j^{th} power supply receives the first setting command and the first position code. A preset value is subtracted from the first position code, the subtracted first position code is stored, and the first setting command and the subtracted first position code are transmitted by the first end of the j^{th} power supply when the j^{th} power supply has the second connection status code. In addition, a preset value is subtracted from the first position code, the subtracted first position code is stored, and a third completion command and the subtracted first position code are transmitted by the second end of the j^{th} power supply when the j^{th} power supply has the third connection status code.

In some embodiments, the k^{th} power supply is determined whether it has the first connection status code or the second connection status code when the first end of the k^{th} power supply receives the second setting command and the second position code. A preset value is added to the second position code, the added second position code is stored, and the second setting command and the added second position code are transmitted by the second end of the k^{th} power supply when the k^{th} power supply has the second connection status code. Besides, a preset value is added to the second position code, the added second position code is stored, and a fourth completion command and the added second position code are transmitted by the first end of the k^{th} power supply when the k^{th} power supply has the first connection status code.

To summarize, the invention provides a method for controlling power supplies, which can know the number of power supplies in the same group, and can make various settings according to the physical position of each power supply. Therefore, when one of the of power supply groups is failed, the engineer can quickly know which power supply in that group is malfunctioned.

### BRIEF DESCRIPTION OF THE APPENDED DRAWINGS

FIG. 1 is a schematic diagram of a power supply system in accordance with an embodiment of the present invention.

FIG. 2 is a flowchart of a method for controlling power supplies in accordance with an embodiment of the present invention.

### DETAILED DESCRIPTION OF THE INVENTION

The features, objections, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

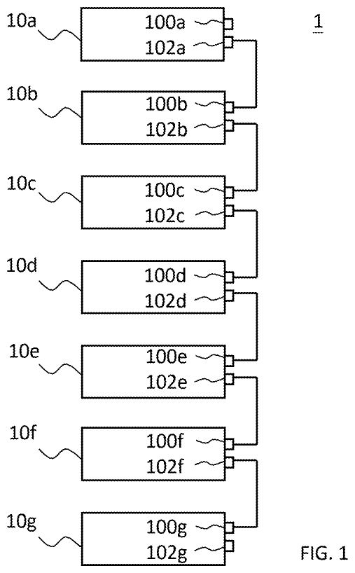

In order to demonstrate the method for controlling power supplies of the present invention, please refer to FIG. 1, FIG. 1 is a schematic diagram of a power supply system in accordance with an embodiment of the present invention. The power supply system 1 can apply the method for controlling power supplies of the present invention. As shown in FIG. 1, the power supply system 1 may have a plurality of power supplies 10a to 10g, each power supply has a first end and a second end, and the first end of the previous power supply is connected to the second end of the next power supply. In practice, the first end of the previous power supply and the second end of the next power supply can be connected via a communication cable. The plurality of power supplies 10a to 10g are able to communicate with each other, and the plurality of power supplies 10a to 10g might be physically stacked together. For example, the communication cable may be an HDMI cable of about 1 meter. In addition, this embodiment does not limit the plurality of power supplies 10a to 10g to communicate only through the communication cables, each power supply might also have other ports to connect to a common bus.

It can be seen from FIG. 1 that the plurality of power supplies 10a to 10g are connected in series to form a tandem series. In this embodiment, when the first power supply of the tandem series can be assumed to be the power supply 10a, the last power supply of the tandem series can be assumed to be the power supply 10g. Other power supplies are connected in the middle of the tandem series. Here, since the power supply 10a is the first power supply of the tandem series, it can be seen that the first end 100a of the power supply 10a is not connected to other power supplies, and only the second end 102a is connected to the first end 100b of the power supply 10b. In addition, since the power supply 10g is already the last power supply of the tandem series, it can be seen that the second end 102g of the power supply 10g is also not connected to other power supplies, and only the first end 100g is connected to the second end 102f of the power supply 10f. The power supply 10c, one of the power supplies in the middle of the tandem series, has the first end 100c and the second end 102c, the first end 100c can be connected to the second end 102b of the power supply 10b, and the second end 102c can also be connected to the first end 100d of the power supply 10d. Thereby, the plurality of power supplies 10a to 10g are connected to each other in form of the first end of the previous power supply connecting and the second end of the next power supply.

Although FIG. 1 illustrates seven power supplies in this embodiment, it is not intended to limit the number of power supplies. Those with ordinary skill in the art can adjust the number of the power supplies. In practice, the power supplies 10a to 10g can be stacked in the first place, and then connected to each other by the communication cable, so that the physical position can correspond to the high-low order of the power supplies 10a to 10g. After the power supplies 10a to 10g are connected to each other, an external computer can be used to give instructions to the power supplies 10a to 10g to start a testing procedure. For example, the external computer can give instructions to start the testing procedure through the bus commonly connected by the power supplies 10a to 10g. Moreover, the testing procedure can also be started by pressing buttons on the power supplies 10a to 10g manually. In addition, in the testing procedure, each power supply will check whether its first end and second end are properly connected.

For example, after the testing procedure, the power supply 10a may know that the first end 100a is not connected, and only the second end 102a is connected. The power supply 10a may store the check result as its connection status code. The connection status code may be recorded as 01 (third connection status code). Similarly, the power supply 10g can know that the second end 102g is not connected, and only the first end 100g is connected. The power supply 10g may store the check result as its connection status code, e.g. 10 (first connection status code). On the other hand, the first end and the second end of each the power supply in the middle of the tandem series are connected. Takes the power supply 10c as an example, both the first end 100c and the second end 102c are connected, the power supply 10c may store the check result as its connection status code, e.g. 11 (second connection status code).

Next, one of the power supplies 10a to 10g can be set as a master power supply by, but not limit to, the external computer. For example, by pressing a button on one of the power supplies 10a to 10g, the power supply whose button is pressed can be set as the master power supply. For convenience of description, the present embodiment sets the power supply 10c as the master power supply. After the power supply 10c is set as the master power supply, the power supply 10c can automatically calculate how many power supplies are connected in the same group. Here, since the connection status code of the power supply 10c is 11 (second connection status code), it means that both the first end 100c and the second end 102c are connected, indicating that the power supply 10c has at least one previous and one next power supply. In order to calculate how many power supplies are arranged in front, the power supply 10c may send a first addressing command and a first accumulated value by the first end 100c. In addition, in order to calculate how many power supplies are arranged in the rear, the power supply 10c can also send a second addressing command and a second accumulated value by the second end 102c. The difference between the first addressing command and the second addressing command is the transmission direction. The first addressing command is a forward transmission command, and the second addressing command is a backward transmission command. The first accumulated value and the second accumulated value are respectively used to calculate how many power supplies are arranged in front or rear, which can be a simple numerical value.

In another example, when the power supply 10a is set as the master power supply, and the connection status code of the power supply 10a is 01 (third connection status code), it means that only the second end 102a is connected, and also means that the power supply 10a only needs to calculate how many power supplies are arranged in the rear. Therefore, when the power supply 10a is set as the master power supply, only the second addressing command and the second accumulated value need to be transmitted by the second end 102a. Conversely, when the power supply 10g is set as the master power supply, the connection status code of the power supply 10g is 10 (the first connection status code), it means that only the first end 100g is connected, and also means that the power supply 10g only needs to calculate how many power supplies are arranged in front. Therefore, when the power supply 10g is set as the master power supply, only the first addressing command and the first accumulated value need to be sent by the first end 100g.

Back to the example of setting the power supply 10c as the master power supply. When the power supply 10b, arranged before the master power supply, receives the first addressing command and the first accumulated value by the second end 102b, the power supply 10b knows from its connection status code, e.g. 11 (second connection status code), that there is at least one power supply arranged before the power supply 10b. Thus, the power supply 10b has to transmit the updated first accumulated value and the first addressing command by the first end 100b. In addition, the first accumulated value transmitted by the power supply 10c may be 0, and the power supply 10b will update the first accumulated value. For example, the updated first accumulated value may be 1, so that the first accumulated value can be used to indicate the number of power supplies arranged in front. Next, the power supply 10a, arranged before the power supply 10b, receives the first addressing command and the first accumulated value by the second end 102a. Because the power supply 10a knows that its connection status code is 01 (third connection status code) indicating that there is no power supply arranged before the power supply 10a. Therefore, after updating the first accumulated value, the power supply 10a may transmit the updated first accumulated value and a first completion command by the second end 102a back to the power supply 10b. In an example, the first accumulated value transmitted by the power supply 10a may be 2.

In other words, the power supply can determine its next action based on the connection status code, such as continuing to transmit the updated first accumulated value and the first addressing command, or returning the updated first accumulated value and first completion command. In addition, when the first end 100b of the power supply 10b receives the first completion command, it will not change the first accumulated value returned by the power supply 10a, and continue to transfer the first completion command and the first accumulated value, returned by the power supply 10a, by the second end 102b. In practice, the first addressing command can be regarded as a command to add 1 to the received first accumulated value and then transmit the updated first accumulated value by the first end. On the other hand, the first completion command can be regarded as a command that maintains the received first accumulated value and transmits the received first accumulated value by the second end. Therefore, after the first end 100c of the power supply 10c receives the first completion command and the returned first accumulated value, the number of power supplies arranged in front of the power supply 10c can be known from the first accumulated value, e.g. 2.

Similarly, when the power supply 10d arranged after the master power supply receives the second addressing command and the second accumulated value by the first end 100d, because the power supply 10d knows from its connection status code, e.g. 11 (second connection status code), that there is at least one power supply arranged behind the power supply 10d. After updating the second accumulated value, the power supply 10d may continue to transmit the updated second accumulated value and the second addressing command by the second end 102d. In an example, the second accumulated value transmitted by the power supply 10c may be 0, and after the power supply 10d updates the second accumulated value, the updated second accumulated value may be 1. Therefore, the second accumulated value can be used to indicate the number of power supplies arranged in the rear. Besides, it can be easily inferred that after the power supply 10f updates the second accumulated value, the updated second accumulated value may be 3.

When the power supply 10g, arranged after the power supply 10f, receives the second addressing command and the second accumulated value from the first end 100g, because the power supply 10g knows from its connection status code, e.g. 10 (first connection status code), that there is no power supply arranged behind the power supply 10g. After updating the second accumulated value, the power supply 10g may transfer the updated second accumulated value and the second completion command by the first end 100g back to the power supply 10f In an example, the second accumulated value transmitted by the power supply 10g may be 4.

When the second end 102f of the power supply 10f receives the second completion command, it will not change the second cumulative value returned by the power supply 10g, and continue to transmit the second completion command and the second cumulative value by the first end 100f In practice, the second addressing command can be regarded as a command to add 1 to the received second accumulated value and then transmit the updated second accumulated value by the second end. On the other hand, the second completion command can be regarded as a command that maintains the received second accumulated value and transmits the received second accumulated value by the first end. Therefore, when the second end 102c of the power supply 10c receives the second completion command and the returned second accumulated value, the number of power supplies arranged after the power supply 10c can be known from the second accumulated value, e.g. 4.

When the power supply 10c receives both the first accumulated value and the second accumulated value, the number of power supplies arranged before and after the power supply 10c can be known, so that the total number of power supplies in the tandem series can be calculated. For example, the number of power supplies arranged before the power supply 10c is 2 (the first accumulated value), the number of power supplies arranged after the power supply 10c is 4 (the second accumulated value), and the power supply 10c further adds 1 to the sum of the first accumulated value and the second accumulated value indicating the power supply 10c itself, the number of the power supplies in the tandem series can be calculated, e.g. 7.

In addition, the master power supply (power supply 10c) may also set the position code of each power supply in the tandem series. First, the power supply 10c can set its own master position code, and the master position code can be calculated from the first accumulated value and the second accumulated value. For example, since the power supply 10c knows that the number of power supplies arranged before itself is 2, the power supply 10c can set its master position code to 3. In an example, the power supply 10c does not need to give the position code of each power supply in the tandem series in advance. Since the power supply 10c has the second connection status code, e.g. 11, it means that there is at least one power supply before the power supply 10c that needs to set the position code, and there is also at least one power supply after the power supply 10c that needs to set the position code. Therefore, the power supply 10c may transmit a first setting command and a first position code by the first end 100c, and the power supply 10c may also transmit the second setting command and the second position code by the second end 102c. In an example, the first position code and the second position code may be, but not limit to, different values or the same value, such as the power supply 10c can transmit the same master position code by the first end 100c and the second end 102c.

Taking the power supply 10c transmits the same master position code by the first end 100c and the second end 102c as an example. When the power supply 10b, arranged before the master power supply, receives the first setting command and the first position code by the second end 102b, since the power supply 10b knows that its connection status code, e.g. 11 (second connection status code), indicates that there is at least one power supply arranged before the power supply 10b. The power supply 10b may update the first position code, and then store the updated first position code in itself. The power supply 10b may continue to transmit the updated first position code and the first setting command by the first end 100b. In an example, the first position code transmitted by the power supply 10c may be 3, and after the power supply 10b updates the first position code, the updated first position code may be 2, so that the first position code can be used to indicate the physical position of the power supply 10b. Next, when the power supply 10a arranged before the power supply 10b receives the first setting command and the first position code by the second end 102a, because the power supply 10a knows that its connection status code, e.g. 01 (third connection status code), indicates that there is no power supply arranged before it. Therefore, the power supply 10a may update the first position code to 1, and store the updated first position code in itself. Then, the power supply 10a may transmit the updated first position code and a third completion command by the second end 102a back to the power supply 10b. In other words, the first position code stored and transmitted by the power supply 10a is 1. In practice, the first setting command can be regarded as subtracting 1 from the received first position code, and then transmitting the updated first position code by the first end (corresponding to the second connection status code) or by the second end (corresponding to the third connection status code). On the other hand, the third completion command can be regarded as a command that maintains the received first position code and transmits the received first position code by the second end.

Similarly, when the power supply 10d, arranged after the master power supply, receives the second setting command and the second position code by the first end 100d, the power supply 10d knows that its connection status code, e.g. 11 (second Connection status code), indicating that there is at least one power supply arranged behind the power supply 10d. The power supply 10d may store the updated second position code after updating the second position code, and then continue to transmit the updated second position code and the second setting command by the second end 102d. In an example, the second position code transmitted by the power supply 10c may be 3, and after the power supply 10d updates the second position code, the updated second position code may be 4, so that the second position code may be used to indicate the physical position of the power supply 10d. Therefore, it can be easily inferred that after the power supply 10f updates the second position code, the updated second position code may be 6.

Next, when the power supply 10g, arranged after the power supply 10f, receives the second setting command and the second position code by the first end 100g, because the power supply 10g knows that its connection status code, e.g. 10 (first connection status code), indicating that there is no power supply arranged after the power supply 10g. The power supply 10g may store the updated second position code after updating the second position code, and then transmit the updated second position code and a fourth completion command by the first end 100g back to the power supply 10f In an example, the second position code stored and transmitted by the power supply 10g may be 7. When the second end 102f of the power supply 10f receives the fourth completion command, it will not change the second position code returned by the power supply 10g, and continue to transfer the fourth completion command and the second position code returned by the power supply 10g by the first end 100f In practice, the second setting command can be regarded as a command to add 1 to the received second position code and then transmit the updated second position code by the second end. On the other hand, the fourth completion command can be regarded as a command that maintains the received second position code and transmits the received second position code by the first end.

When the power supply 10c receives the returned third completion command and the fourth completion command, it means that all the power supplies have stored their own position codes. For example, the position codes 1˜7 can correspond to the power supplies 10a˜10g. In addition, after the power supply 10c receives the first position code and the second position code, it can also check whether the total number of power supplies in the tandem series is correct according to the sum of the first position code and the second position code.

In other embodiments, the master power supply may test whether the communication between the tandem series of power supplies is normal. Assuming the power supply 10c is the master power supply, the power supply 10c can transmit the same test command by the first end 100c and the second end 102c (for example, a specific value corresponds to multiple bits). When the previous power supply 10b receives the test command by the second end 102b, the content of the test command will not be changed, and the test command is directly transmitted by the first end 100b. When the power supply 10a receives the test command by the second end 102a, the power supply 10a knows that its connection status code is 01 (third connection status code), it means that there is no power supply arranged before the power supply 10a. Therefore, the power supply 10a may directly transmit the test command from the second end 102a by to the previous power supply 10b. In an example, the test command transmitted by the power supply 10c may be 00100100. If the test command received by the power supply 10c is 00101000, it can be known that two bits of the test command are interfered.

Therefore, the master power supply can know how bad is the environmental interference. If the environmental interference is severe, in order to improve the SN ratio of the power supplies, the master power supply can add several check bits to all commands and values to eliminate the impact of the environmental interference. In practice, the power supply 10c can repeatedly transmit the same test command from the first end 100c and the second end 102c, and periodically calculate how many bits in the test command are interfered.

In other embodiments, the master power supply may also calculate an average output voltage or current between of the power supplies. In an example, if the average current output by the power supplies is to be measured, the power supply 10c may transmit a first current calculation command and a first accumulated current value by the first end 100c, and transmit a second current calculation command and the second accumulated current value by the second end 102c. When the power supply 10b receives the first current calculation command by the second end 102b, the current value of the power supply 10b is accumulated on the first current accumulated value. And then, the first current calculation command and the updated first current accumulated value continue to be transmitted by the first end 100b. When the power supply 10a receives the first current calculation command by the second end 102a, the power supply 10a can continue to accumulate its current value on the first current accumulated value, and return a first calculation completion command and the updated first current accumulated value by the second end 102a back to the power supply 10b.

When the first end 100b of the power supply 10b receives the first calculation completion instruction, it will not change the first current accumulated value returned by the power supply 10a, and will continue to transmit the first calculation completion command and the first current accumulated value to the power supply 10a by the second end 102b. Thereby, the power supply 10c (master power supply) can know the total output current of the power supplies arranged in front. Similarly, the power supply 10c may receive the returned second current accumulated value by the second end 102c and can know the total output current of the power supplies arranged in the rear. The method for calculating the second current accumulated value is similar to the method for calculating the first current accumulated value, which will not be repeated here. Therefore, the power supply 10c add the total output current of the front and rear power supplies and its own output current to obtain the total output current of the power supplies. In practice, it is possible to calculate the average voltage, the average power, the average working time, or other known parameters of the power supplies.

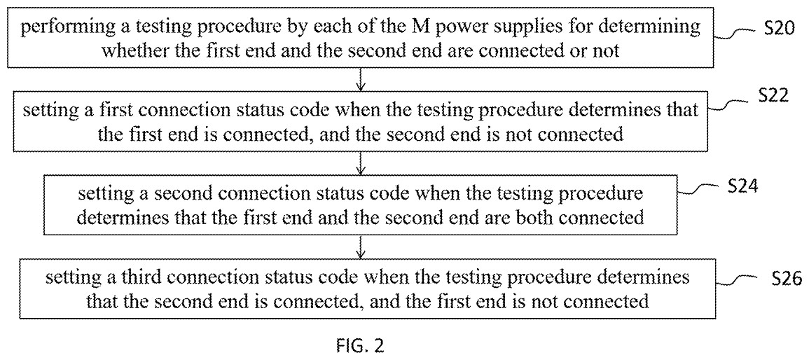

The above embodiments use the power supply system 1 to explain the method for controlling power supplies of the present invention. Please FIG. 1 and FIG. 2 together, FIG. 2 is a flowchart of the method for controlling power supplies in accordance with an embodiment of the present invention. As shown in figures, in step S20, after the power supplies 10a to 10g are connected, a command of the testing procedure can be given. In the testing procedure, each power supply checks whether its first end and second end are properly connected. In step S22, the power supply 10g knows that the second end 102g is not connected, and only the first end 100g is connected. At this time, the power supply 10g may store the check result as its connection status code, for example, it may be recorded as 10 (first connection status code). In step S24, the first end 100c and the second end 102c of the power supply 10c, in the middle of the tandem series, are connected. At this time, the power supply 10c may store the check result as its connection status code, for example, it may be recorded as 11 (second connection status code). In step S26, the power supply 10a knows that the first end 100a is not connected, and only the second end 102a is connected. At this time, the power supply 10a may store the check result as its connection status code, for example, it may be recorded as 01 (third connection status code). As for the other steps of the method, they have been fully described in the foregoing embodiments and will not be repeated here.

To summarize, the invention provides a method for controlling power supplies, which can know the number of power supplies in the same group, and can make various settings according to the physical position of each power supply. Therefore, when one of the of power supply groups is failed, the engineer can quickly know which power supply in that group is malfunctioned.

What is claimed is:

1. A method for controlling power supplies that applies to M power supplies, each power supply has a first end and a second end, the first end of the i^{th} power supply is connected to the second end of the (i−1)^{th} power supply, the method comprising:
performing a testing procedure by each of the M power supplies for determining whether the first end and the second end are connected or not;
setting a first connection status code when the testing procedure determines that the first end is connected, and the second end is not connected;
setting a second connection status code when the testing procedure determines that the first end and the second end are both connected; and
setting a third connection status code when the testing procedure determines that the second end is connected, and the first end is not connected;
wherein M is a natural number greater than 2, and i is a natural number not less than 2 and not greater than M.

2. The method for controlling power supplies according to claim 1, further comprising:
setting one of the M power supplies as a master power supply;
determining whether the master power supply has the first connection status code, the second connection status code, or the third connection status code;
transmitting a first addressing command and a first accumulated value by the first end of the master power supply when the master power supply has the first connection status code;
transmitting the first addressing command and the first accumulated value by the first end of the master power supply, and transmitting a second addressing command and a second accumulated value by the second end of the master power supply when the master power supply has the second connection status code; and
transmitting the second addressing command and the second accumulated value by the second end of the master power supply when the master power supply has the third connection status code.

3. The method for controlling power supplies according to claim 2, further comprising:
determining the j^{th} power supply having the second connection status code or the third connection status code when the second end of the j^{th} power supply receives the first addressing command and the first accumulated value;
wherein j is a natural number not greater than M.

4. The method for controlling power supplies according to claim 3, further comprising:
updating the first accumulated value, and transmitting the first addressing command and the updated first accumulated value by the first end of the j^{th} power supply when the j^{th} power supply has the second connection status code.

5. The method for controlling power supplies according to claim 3, further comprising:
updating the first accumulated value, and transmitting a first completion command and the updated first accumulated value by the second end of the j^{th} power supply when the j^{th} power supply has the third connection status code.

6. The method for controlling power supplies according to claim 5, further comprising:
maintaining the first accumulated value, and transmitting the first completion command and the first accumulated value by the second end of the j^{th} power supply when the first end of the j^{th} power supply receives the first completion command and the first accumulated value.

7. The method for controlling power supplies according to claim 2, further comprising:
determining the k^{th} power supply having the first connection status code or the second connection status code when the first end of the k^{th} power supply receives the second addressing command and the second accumulated value;
wherein k is a natural number not greater than M.

8. The method for controlling power supplies according to claim 7, further comprising:
updating the second accumulated value, and transmitting the second addressing command and the updated second accumulated value by the second end of the k^{th} power supply when the k^{th} power supply has the second connection status code.

9. The method for controlling power supplies according to claim 7, further comprising:
updating the second accumulated value, and transmitting a second completion command and the updated second accumulated value by the first end of the k^{th} power supply when the k^{th} power supply has the first connection status code.

10. The method for controlling power supplies according to claim 9, further comprising:
maintaining the second accumulated value, and transmitting the second completion command and the second accumulated value by the first end of the k^{th} power supply when the second end of the k^{th} power supply receives the second completion command and the second accumulated value.

11. The method for controlling power supplies according to claim 2, further comprising:
calculating the number of the M power supplies at least according to the first accumulated value received by the first end of the master power supply or the second accumulated value received by the second end of the master power supply.

12. The method for controlling power supplies according to claim 11, further comprising:
setting a master position code of the master power supply at least according to the first accumulated value or the second accumulated value.

13. The method for controlling power supplies according to claim 12, further comprising:
transmitting a first setting command and a first position code by the first end of the master power supply when the master power supply has the first connection status code;
transmitting the first setting command and the first position code by the first end of the master power supply, and transmitting a second setting command and a second position code by the second end of the master power supply when the master power supply has the second connection status code; and
transmitting the second setting command and the second position code by the second end of the master power supply when the master power supply has the third connection status code;
wherein the first position code and the second position code are related to the master position code.

14. The method for controlling power supplies according to claim 13, further comprising:
determining the j^{th} power supply having the second connection status code or the third connection status code when the second end of the j^{th} power supply receives the first setting command and the first position code;
wherein j is a natural number not greater than M.

15. The method for controlling power supplies according to claim 14, further comprising:
subtracting a preset value from the first position code, storing the subtracted first position code, and transmitting the first setting command and the subtracted first position code by the first end of the j^{th} power supply when the j^{th} power supply has the second connection status code.

16. The method for controlling power supplies according to claim 14, further comprising:
subtracting a preset value from the first position code, storing the subtracted first position code, and transmitting a third completion command and the subtracted first position code by the second end of the j^{th} power supply when the j^{th} power supply has the third connection status code.

17. The method for controlling power supplies according to claim 16, further comprising:
maintaining the first position code, and transmitting the third completion command and the first position code by the second end of the j^{th} power supply when the first end of the j^{th} power supply receives the third completion command and the first position code.

18. The method for controlling power supplies according to claim 13, further comprising:
determining the k^{th} power supply having the first connection status code or the second connection status code when the first end of the k^{th} power supply receives the second setting command and the second position code;
wherein k is a natural number not greater than M.

19. The method for controlling power supplies according to claim 18, further comprising:
adding a preset value to the second position code, storing the added second position code, and transmitting the second setting command and the added second position code by the second end of the k^{th} power supply when the k^{th} power supply has the second connection status code.

20. The method for controlling power supplies according to claim 18, further comprising:
adding a preset value to the second position code, storing the added second position code, and transmitting a fourth completion command and the added second position code by the first end of the k^{th} power supply when the k^{th} power supply has the first connection status code.

21. The method for controlling power supplies according to claim 20, further comprising:
maintaining the second position code, and transmitting the fourth completion command and the second position code by the first end of the k^{th} power supply when the second end of the k^{th} power supply receives the fourth completion command and the second position code.

22. The method for controlling power supplies according to claim 13, further comprising:
calculating the number of the M power supplies at least according to the first position code received by the first end of the master power supply or the second position code received by the second end of the master power supply.
